(19) United States
(12) Patent Application Publication
(10) Pub. No.: US 2015/0143910 A1
(43) Pub. Date: May 28, 2015

(54) ULTRASONIC TRANSMITTER CIRCUIT WITH MATCHED IMPEDANCE

(71) Applicant: EDDYFI NDT INC., Québec (CA)

(72) Inventors: Florian Hardy, Saint-Augustin-de-Desmaures (CA); Eric Morissette, Quebec (CA)

(73) Assignee: EDDYFI NDT INC., Quebec (CA)

(21) Appl. No.: 14/409,011

(22) PCT Filed: Jul. 23, 2013
(86) PCT No.: PCT/IB2013/056039

§ 371 Date: Dec. 18, 2014

Related U.S. Application Data
(60) Provisional application No. 61/674,978, filed on Jul. 24, 2012.

(51) Int. Cl. G01B 17/02; H03H 7/38

(52) U.S. Cl. CPC G01B 17/02; H03H 7/38
USPC 73/629

(57) ABSTRACT

A transmitter circuit and method for an ultrasonic thickness measurement system having an ultrasonic transducer and a cable with known cable impedance, the cable connecting at least the transmitter circuit to the ultrasonic transducer, the transmitter circuit comprising: an electrical pulse voltage signal emitter for producing an electrical pulse voltage signal to be propagated over the cable to the ultrasonic transducer, the electrical pulse voltage signal having a pulse nominal voltage value; a matched impedance circuit for matching a cable impedance of the cable at the transmitter circuit for an electrical parasitic reflection signal of the electrical pulse voltage signal, the electrical parasitic reflection signal being caused by an impedance mismatch between the cable and the ultrasonic transducer, a parasitic nominal voltage value of the electrical parasitic reflection signal being at most the pulse nominal voltage value.

### TECHNICAL FIELD

The invention relates to non-destructive testing using ultrasonic techniques. More particularly, the invention is applicable to inspection techniques using an ultrasonic transducer linked by a cable to the transmitter-receiver or transmitter circuit, where the transmitter sends unipolar or bipolar pulse wave voltage signals to the ultrasonic transducer through the cable.

### BACKGROUND OF THE ART

The ultrasonic transducer converts the voltage pulse to mechanical movement mainly oriented perpendicularly in the direction of the emission surface of the transducer. This mechanical movement produces the ultrasonic wave in the transmission medium. There are many types of transmission mediums, including liquids, gels, plastic wedges, etc. For thickness measurement applications, the part under test is located perpendicular to the main direction of propagation of the ultrasonic wave to make sure that the wave strikes the surface of the part under test perpendicularly. Ultrasonic mirrors can be used to change the direction of the ultrasonic wave and make sure that the ultrasonic wave strikes the surface of the part under test perpendicularly.

When the ultrasonic wave strikes the surface of the part under test, a portion of the ultrasonic wave is reflected, like a sound echo, and a portion is transmitted into the material of the part under test. The same transducer or a different transducer can be used to receive the reflected wave and convert it into a signal voltage called front wall echo. The front wall echo signal is amplified and conditioned by the receiver circuit. In the mean time, the transmitted ultrasonic wave in the material of the part under test strikes the opposite surface of the part under test and a portion of the ultrasonic wave is reflected and comes back to the transducer used to receive the ultrasonic echoes. The transducer converts this second ultrasonic wave to a signal voltage called back wall echo. The electronic equipment receiving both the front wall echo and the back wall echo detects them and then determines the time interval between both echoes. This time interval corresponds to the additional time the ultrasonic wave has taken to propagate back and forth in the part under test. Usually, the speed of sound in the part under test is known. For thickness measurement applications, the thickness is equal to the speed of sound in the material multiplied by the time interval between the 2 echoes divided by 2.

This technique of thickness measurement can be used to measure the thickness of each layer for a multilayer part, based on each time interval found between the echoes.

In some inspection applications, the transducer and the transmitter-receiver or transmitter circuit are connected by a long cable because the location at which the transducer should be located is too small. Tube inspection from the inside is a good example of a testing environment where a long coaxial cable is required to connect the transmitter-receiver or transmitter circuit to the transducer because the tube inside diameter can only allow for the transducer to be inserted therein.

The ultrasonic transducer has complex impedance which greatly varies with the frequency. The emitted pulse is sent from the transmitter circuit to the transducer over the coaxial cable and a large portion of the pulse signal is reflected back in the coaxial cable towards the transmitter circuit because the transducer impedance does not match the coaxial cable impedance. The reflected pulse signal goes back to the transmitter-receiver or transmitter circuit which also has no matched impedance with the coaxial cable impedance. This impedance mismatch causes another reflection which creates another pulse at the transmitter circuit going back towards the transducer. The second transmitted pulse is delayed in time relative to the first pulse emitted by the transmitter circuit. The second transmitted pulse is smaller in amplitude, but it is important enough to cause a second ultrasonic wave in the material under test. This second wave produces another front wall echo. This second front wall echo is a parasitic signal that might get superposed to the back wall echo when the thickness of the layer under test produces a time interval close to the time interval between the first and second transmit pulses. In that case, the wall thickness is not measured with a fair level of confidence because the back wall echo cannot be precisely identified.

### SUMMARY

In an ultrasonic thickness measurement system using a cable between the transmitter circuit and the transducer, the wall thickness measurement range can be expanded to thinner material thickness values using a matched impedance circuit which contributes to reduce reflections in the cable.

According to one broad aspect of the present invention, there is provided a transmitter circuit for an ultrasonic thickness measurement system having an ultrasonic transducer, a receiver circuit and a cable with known cable impedance, the cable connecting at least the transmitter circuit to the ultrasonic transducer. The transmitter circuit comprises an electrical pulse voltage signal emitter for producing an electrical pulse voltage signal to be sent over the cable to the ultrasonic transducer, the electrical pulse voltage signal having a pulse nominal voltage value; a matched impedance circuit in the transmitter circuit, the matched impedance circuit matching the cable impedance of the cable at the transmitter circuit for a electrical parasitic reflection signal of the electrical pulse voltage signal, the electrical parasitic reflection signal being caused by an impedance mismatch between the cable and the ultrasonic transducer, a parasitic nominal voltage value of the electrical parasitic reflection signal being at most the pulse nominal voltage value.

In one embodiment, a shape of the electrical parasitic reflection signal has at least one of a positive component and an inverted component.

In one embodiment, the receiver circuit and the transmitter circuit are provided by a single transmission-reception circuit and wherein the cable connects the transmitter-reception circuit to the ultrasonic transducer.

According to another broad aspect of the present invention, there is provided a method for reducing an impact of an electrical parasitic reflection signal in an ultrasonic measurement system having a transmitter circuit, a transmission ultrasonic transducer and a transmission cable with known cable impedance, the transmission cable connecting at least the transmitter circuit to the transmission ultrasonic transducer. The method comprises emitting an electrical pulse voltage signal at the transmitter circuit; sending the electrical pulse voltage signal having a pulse nominal voltage value over the transmission cable to the transmission ultrasonic transducer in a transmission medium; receiving, at the transmitter circuit, an electrical parasitic reflection signal caused by an impedance mismatch between the transmission cable and the transmission ultrasonic transducer, a parasitic nominal voltage value of the electrical parasitic reflection signal being at most the pulse nominal voltage value; matching an impedance of the transmission cable at the transmitter circuit for the electrical parasitic reflection signal.

In one embodiment, the method further comprises receiving a front wall voltage signal and at least one second wall voltage signal at a receiver circuit; determining a thickness for a material using a speed of sound in the material and a time interval between the receiving the front wall voltage signal and receiving the at least one second wall voltage signal at the receiver circuit.

In one embodiment, the front wall voltage signal and the at least one second wall voltage signal are provided by: transforming the electrical pulse voltage signal into an ultrasonic wave traveling in the transmission medium at the ultrasonic transmission transducer; receiving a front wall ultrasonic echo wave and at least a second wall ultrasonic echo wall from the material at a receiving ultrasonic transducer; transforming the front wall ultrasonic echo wave into the front wall voltage signal at the receiving ultrasonic transducer and transforming the at least the second wall ultrasonic echo wall into the at least one second wall voltage signal at the receiving ultrasonic transducer, wherein the front wall voltage signal has a front wall nominal value and the at least the second wall voltage signal has a second wall nominal value; sending the front wall voltage signal and the at least one second wall voltage signal over a reception cable to the receiver circuit.

According to another broad aspect of the present invention, there is provided a method for measuring a thickness of a material, comprising: emitting an electrical pulse voltage signal at a transmitter circuit; sending the electrical pulse voltage signal having a pulse nominal voltage value over a transmission cable to a transmission ultrasonic transducer in a transmission medium; receiving, at the transmitter circuit, an electrical parasitic reflection signal caused by an impedance mismatch between the transmission cable and the transmission ultrasonic transducer, a parasitic nominal voltage value of the electrical parasitic reflection signal being at most the pulse nominal voltage value; matching an impedance of the transmission cable at the transmitter circuit for the electrical parasitic reflection signal; transforming the electrical pulse voltage signal into an ultrasonic wave traveling in the transmission medium at the ultrasonic transmission transducer; receiving a front wall ultrasonic echo wave and at least a second wall ultrasonic echo wall from the material at a receiving ultrasonic transducer; transforming the front wall ultrasonic echo wave into a front wall voltage signal at the receiving ultrasonic transducer and transforming the at least the second wall ultrasonic echo wall into at least one second wall voltage signal at the receiving ultrasonic transducer, wherein the front wall voltage signal has a front wall nominal value and the at least the second wall voltage signal has a second wall nominal value; sending the front wall voltage signal and the at least one second wall voltage signal over a reception cable to a receiver circuit; receiving the front wall voltage signal and the at least one second wall voltage signal at the receiver circuit; determining the thickness for the material using a speed of sound in the material and a time interval between the receiving the front wall voltage signal and receiving the at least one second wall voltage signal at the receiver circuit.

In one embodiment, the transmission ultrasonic transducer and the receiving ultrasonic transducer are provided by a single transmission-reception ultrasonic transducer and wherein the transmission cable and the reception cable are provided by a single transmission-reception cable.

In one embodiment, the pulse nominal voltage value is between −50 V and −400 V.

In one embodiment, the front wall nominal value and the second wall nominal value is between −1 V and 1 V.

In one embodiment, the method further comprises changing a direction of the ultrasonic wave using an ultrasonic mirror to allow the ultrasonic wave to strike the material perpendicularly.

According to another broad aspect of the present invention, there is provided a transmitter circuit for an ultrasonic thickness measurement system having an ultrasonic transducer and a cable with known cable impedance, the cable connecting at least the transmitter circuit to the ultrasonic transducer, the transmitter circuit comprising: an electrical pulse voltage signal emitter for producing an electrical pulse voltage signal to be propagated over the cable to the ultrasonic transducer, the electrical pulse voltage signal having a pulse nominal voltage value; a matched impedance circuit for matching a cable impedance of the cable at the transmitter circuit for an electrical parasitic reflection signal of the electrical pulse voltage signal, the electrical parasitic reflection signal being caused by an impedance mismatch between the cable and the ultrasonic transducer, a parasitic nominal voltage value of the electrical parasitic reflection signal being at most the pulse nominal voltage value.

In one embodiment, a shape of the electrical parasitic reflection signal has at least one of a positive component and a negative component.

In one embodiment, the cable impedance of the cable is one of 50, 75, 93 and 95 Ohms.

In one embodiment, the pulse nominal voltage value is between −50 V and −400 V.

In one embodiment, the matched impedance circuit is at least one resistance provided in the transmitter circuit to impact a circuit impedance of the transmitter circuit for the electrical parasitic reflection signal, the circuit impedance matching the cable impedance.

In one embodiment, the matched impedance circuit further includes at least one diode, the at least one diode controlling an effect of the at least one resistance on the circuit impedance.

In one embodiment, the matched impedance circuit is one resistance in series with a diode in which current circulates during transmission of the electrical pulse voltage signal.

In one embodiment, the matched impedance circuit is one resistance in series with a diode in which current circulates after the transmission of the electrical pulse voltage signal has ended.

According to another broad aspect of the present invention, there is provided a method for reducing an impact of an electrical parasitic reflection signal in an ultrasonic measurement system having a transmitter circuit, an ultrasonic transducer and a cable with known cable impedance, the cable connecting at least the transmitter circuit to the ultrasonic transducer, comprising: emitting an electrical pulse voltage signal at the transmitter circuit; propagating the electrical pulse voltage signal having a pulse nominal voltage value over the cable to the ultrasonic transducer; receiving, at the transmitter circuit, an electrical parasitic reflection signal caused by an impedance mismatch between the cable and the ultrasonic transducer, a parasitic nominal voltage value of the electrical parasitic reflection signal being at most the pulse nominal voltage value; matching an impedance of the cable at the transmitter circuit for the electrical parasitic reflection signal.

In one embodiment, a shape of the electrical parasitic reflection signal has at least one of a positive component and a negative component.

In one embodiment, the cable impedance of the cable is one of 50, 75, 93 and 95 Ohms.

In one embodiment, the pulse nominal voltage value is between −50 V and −400 V.

In one embodiment, the matching comprises providing at least one resistance in the transmitter circuit to impact a circuit impedance of the transmitter circuit for the electrical parasitic reflection signal, the circuit impedance matching the cable impedance.

In one embodiment, the matching further comprises providing at least one diode, the at least one diode controlling an effect of the at least one resistance on the circuit impedance.

In one embodiment, matching comprises providing one resistance in series with a diode in which current circulates during transmission of the electrical pulse voltage signal.

In one embodiment, the matching comprises providing one resistance in series with a diode in which current circulates after the transmission of the electrical pulse voltage signal has ended.

### BRIEF DESCRIPTION OF THE DRAWINGS

Having thus generally described the nature of the invention, reference will now be made to the accompanying drawings, showing by way of illustration an example embodiment thereof and in which:

FIG. 1 is an example of an ultrasonic wall thickness measurement system using a cable between the transducer and the electronics;

FIG. 2A (prior art) is an example of an ultrasonic signal after the first stage of amplification obtained on thick material; FIG. 2B (prior art) is an example of an ultrasonic signal after the first stage of amplification obtained on thin material; FIG. 2C is an example of an ultrasonic signal after the first stage of amplification obtained on the thin material of FIG. 2B with the impedance matching circuit present;

FIG. 3A (prior art) is an example conventional electronic circuit design for a unipolar transmitter coupled with a MOSFET as the input of the amplifier receiver; FIG. 3B is an example impedance matching circuit for a unipolar transmitter coupled directly to the amplifier receiver;

FIG. 4A (prior art) is an example conventional electronic circuit design for a unipolar transmitter coupled with a bridge of diodes as the input of the amplifier receiver; and FIG. 4B is an example impedance matching circuit for a unipolar transmitter coupled with a bridge of diodes as input of the amplifier receiver; and

FIG. 5A (prior art) and FIG. 5B (prior art) show example signals at the output of the transmitter circuit (FIG. 5A) and at the input of the transducer (FIG. 5B), FIG. 5C and FIG. 5D show example signals in the test environment of FIG. 5A and FIG. 5B with the matched impedance circuit being provided in the transmitter circuit, at the output of the transmitter circuit (FIG. 5C) and at the input of the transducer (FIG. 5D).

It will be noted that throughout the appended drawings, like features are identified by like reference numerals.

### DETAILED DESCRIPTION

The invention consists in an impedance-matching circuit of the transmitter-receiver or transmitter circuit which contributes to reduce the impact of the reflection of the pulse signal on the transducer back towards the transmitter-receiver or transmitter circuit. By matching the impedance of the transmitter-receiver circuit with the impedance of the coaxial cable, the pulse energy is mainly transferred in the circuit and there is no strong reflection back towards the transducer.

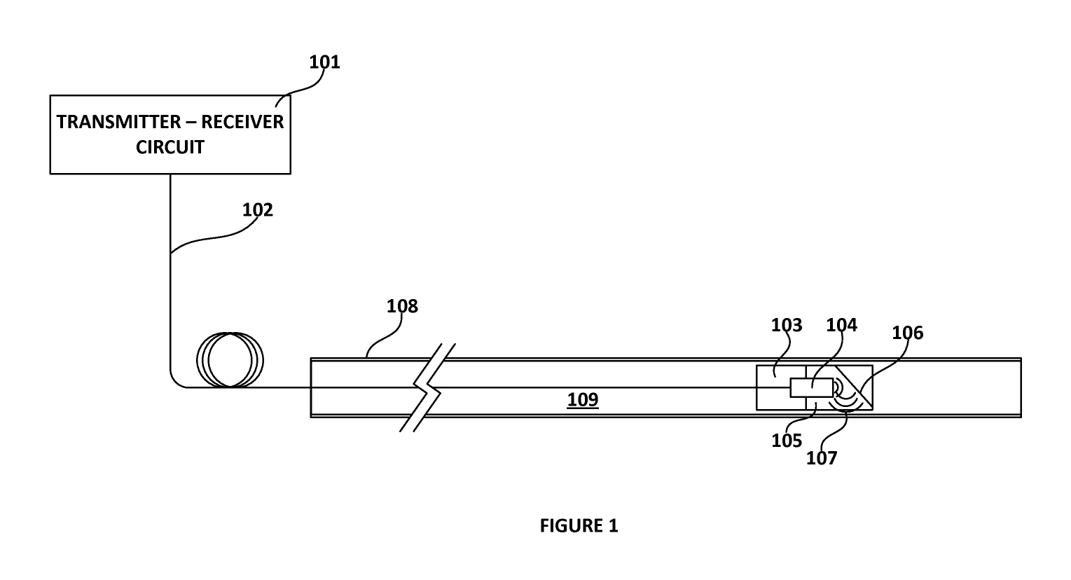

FIG. 1 shows a diagram of some elements of an example tube wall thickness testing system. The transmit-receiver circuit 101 is used to generate the pulse voltage signal sent to the transducer 104 and to amplify the echo signals received from the transducer 104. In this example, the tube to inspect 108 is 25 m long. The coaxial cable 102 is used to connect the transmitter-receiver circuit 101 to the transducer 104. The coaxial cable 102 is long, for example, 30 m long. The nominal impedance of the coaxial cable 102 is, for example, 50 Ω.

An ultrasonic wave 107 is emitted by the transducer 104 when the pulse voltage transmitted by the transmitter-receiver circuit over the cable 102 arrives on the transducer 104. There is a short time interval between the time the pulse is emitted from the transmitter-receiver circuit 101, passes through the coaxial cable 102 and arrives at the transducer 104. This time interval depends on the electrical signal propagation speed in the cable and on the cable length. For this example, the electrical signal propagation speed is 2×10⁸ m/s and the coaxial cable length is 30 m. The time interval is equal to the coaxial cable length divided by the electrical signal propagation speed in the coaxial cable. A time interval of 150 ns (30 m/(2×10⁸ m/s)) is obtained.

There is a rotating mirror 106 used to change the direction of the ultrasonic wave with respect to the tube. The rotation of the mirror 106 controls the angular position of the ultrasonic wave with the circumference of the tube 108. The rotation of the mirror is done by a turbine. The stator 103 of the turbine does not turn and the rotor 105 of the turbine turns. In this example, the tube is filled with water 109.

The impedance of the transducer 104 does not match the 50Ω of the coaxial cable 102 and this mismatch produces a reflection of the transmitted pulse in the coaxial cable 102. This reflection runs in the coaxial cable at the same speed as previously and then arrives at the transmitter-receiver with an additional time interval of 150 ns. The impedance matching circuit contributes to avoid another reflection of the signal back from the transmitter-receiver circuit to the transducer 104.

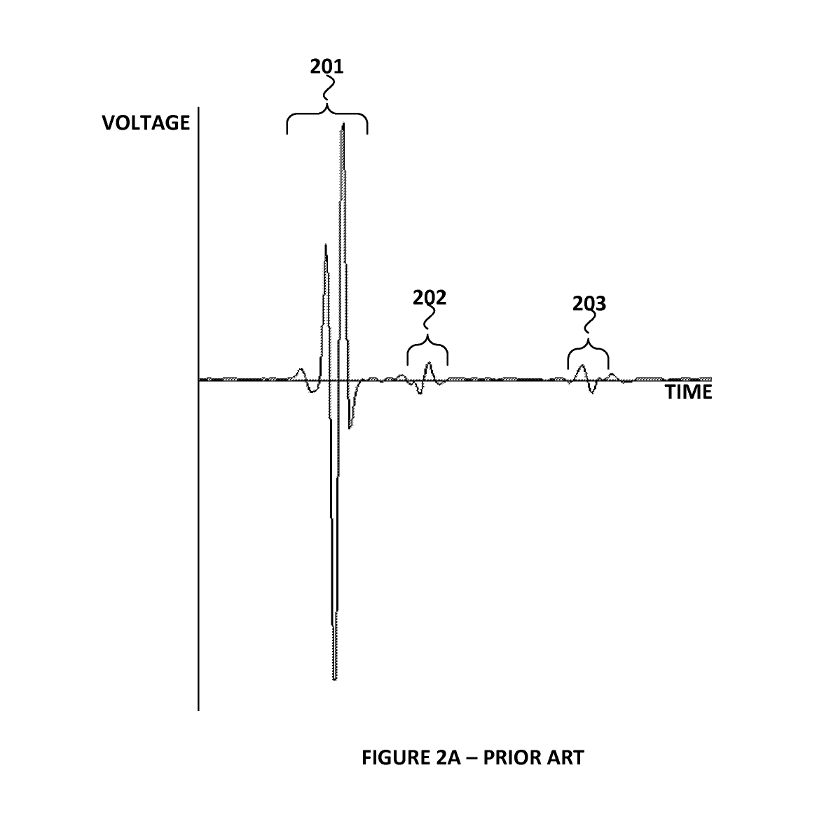

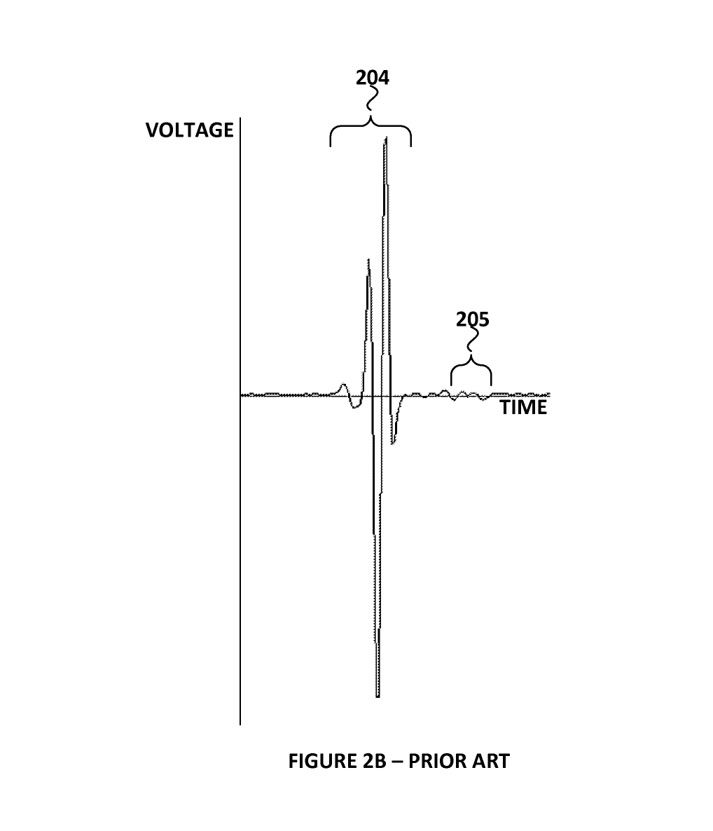

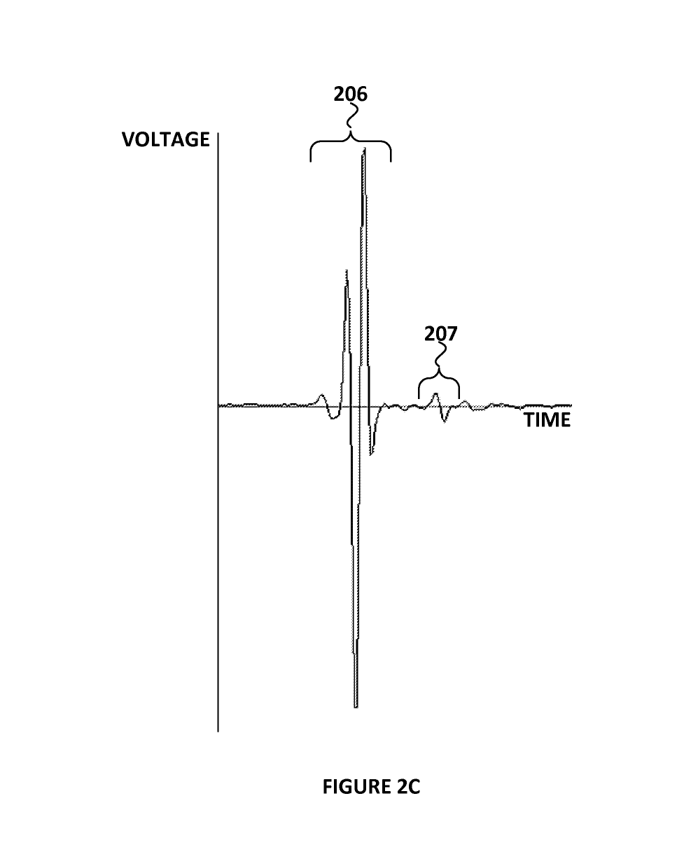

FIG. 2A (prior art) shows an example of a signal obtained at the output of the receiver circuit. The horizontal axis is the time and the vertical axis is the signal voltage. The front wall echo 201 is the dominant signal with few associated oscillations. There is a second front wall echo 202 delayed by about 300 ns relative to the first front wall echo 201. This time delay between the first and second front wall echoes is due to the reflection of the pulse signal in the coaxial cable, which corresponds in this example to 150 ns for each way. The back wall echo 203 is about 800 ns later than the front wall echo 201. This delay depends on the thickness of the material and on the ultrasound wave speed in the part under test. In this example, the sound velocity is 5000 m/s and the wall thickness is 2 mm (5000 m/s×800 ns/2).

In FIG. 2B (prior art), the wall thickness of the material is 0.75 mm. In that case, the front wall echo 204 does not really change, but the back wall echo moves to the left because the wall is thinner. The back wall echo is moved to about 300 ns (0.75 mm×2/5000 m/s) from the front wall which corresponds to the position of second front wall echo. The result is that the second front wall echo and the back wall echo are superposed 205. In this example, it is not possible to locate the back wall echo accurately.

In FIG. 2C, the transmitter-receiver circuit has been modified with a matched impedance circuit as per the present invention. The other components are unchanged and equivalent to those of FIG. 2B. The front wall echo 206 does not really change, but the back wall echo signal 207 can now be located accurately because the second front wall echo is strongly reduced.

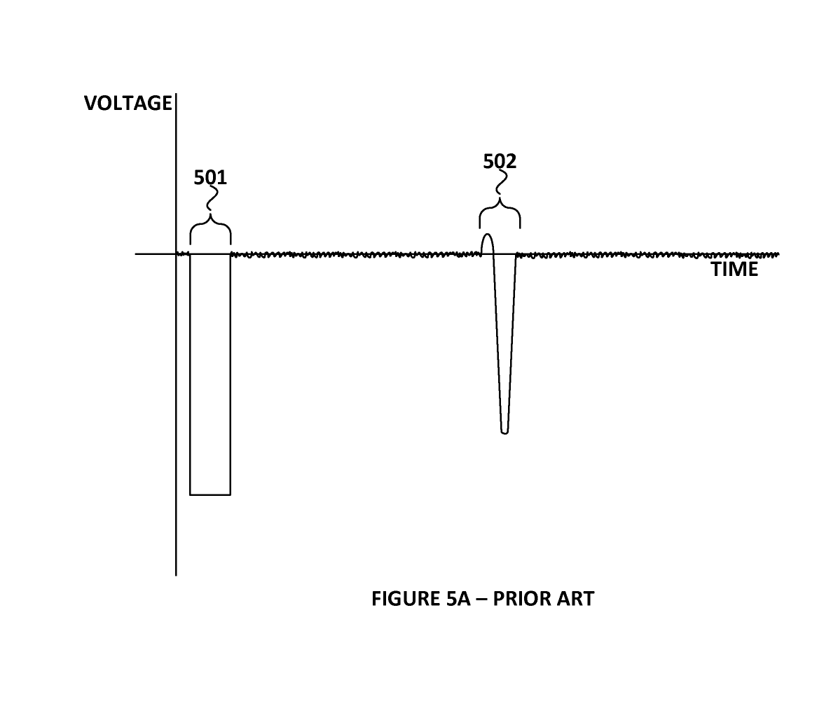

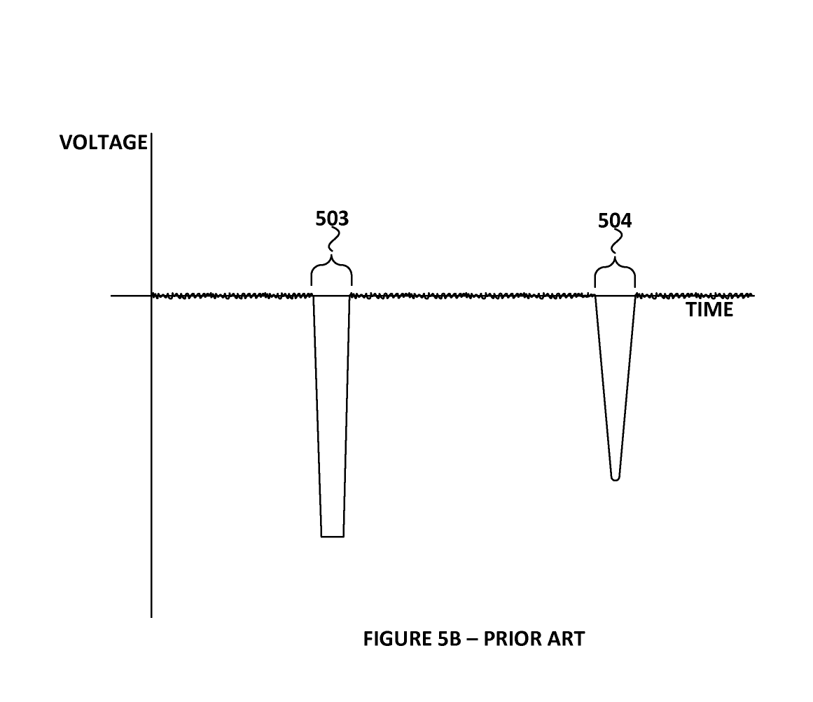

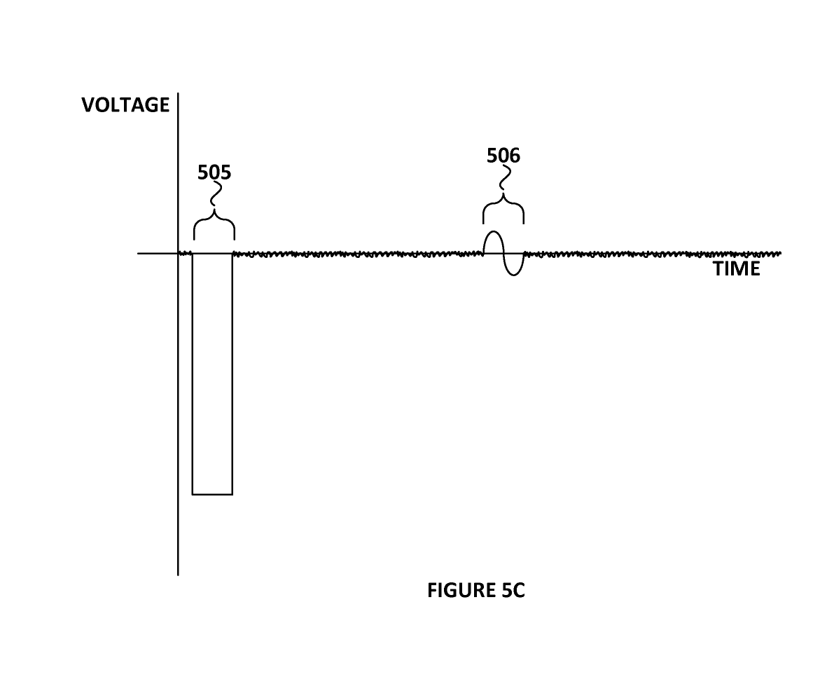

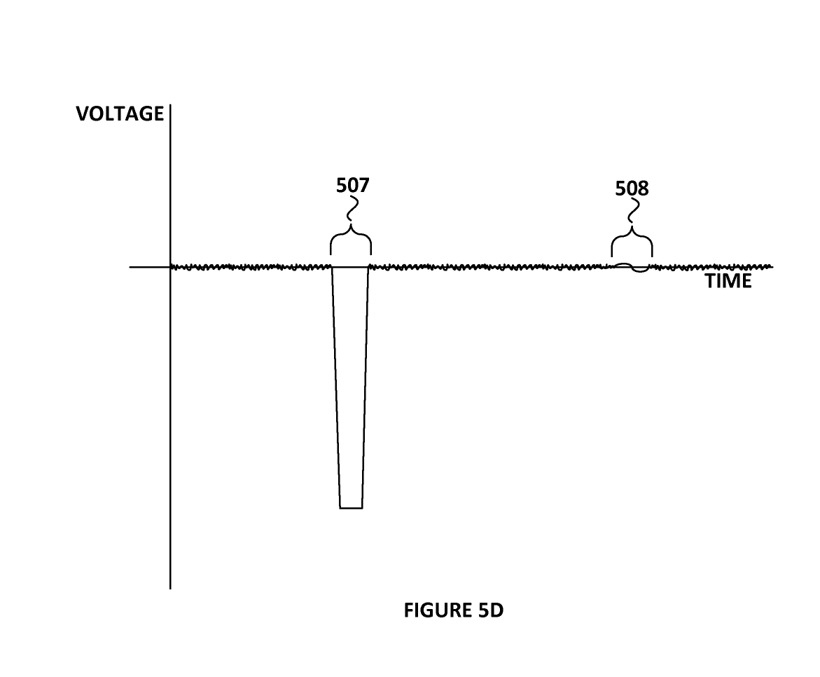

FIG. 5A (prior art) and FIG. 5B (prior art) show example signals at the output of the transmitter circuit (FIG. 5A) and at the input of the transducer (FIG. 5B). The initial pulse 501 emitted by the transmitter circuit is propagated to the transducer at the electrical signal propagation speed in the coaxial cable. After the delay of propagation in the cable, the first pulse 503 arrives at the transducer. The first pulse 503 causes the transducer to create a first ultrasonic wave in the material, for which a front wall echo and a back wall echo will be received. The complex impedance of the transducer also produces a reflection in the cable which may have positive and negative components. The once-reflected signal is propagated back in the cable and arrives at the transmitter. The once-reflected signal is again reflected at the transmitter circuit due to the unmatched impedance between the cable and the transmitter circuit. The twice-reflected signal 502 is deformed (when compared to the initial pulse 501) due to the unmatched impedance. In this example, the positive component sees low impedance whereas the negative portion of the reflected signal sees high impedance. The twice-reflected signal 502 travels towards the transducer. The twice-reflected signal which arrives at the transducer 504 is a second electrical pulse which, from the transducer's perspective, appears to come from the transmitter. The second pulse 504 causes the transducer to create a second ultrasonic wave in the material, for which a front wall echo and a back wall echo will be received. If the front wall echo of the second pulse 504 superposes in time with the back wall echo of first pulse 503, it causes an ambiguity.

FIG. 5C and FIG. 5D show example signals in the test environment of FIG. 5A and FIG. 5B with a matched impedance circuit as per the present invention being provided in the transmitter circuit, at the output of the transmitter circuit (FIG. 5C) and at the input of the transducer (FIG. 5D). The initial pulse 505 emitted by the transmitter is sent to the transducer over the coaxial cable. After the transmission delay the first pulse signal 507 arrives at the transducer. There is a signal reflection at the transducer and then the once-reflected signal goes back to the transmitter circuit. The once-reflected signal arrives at the transmitter circuit after the propagation delay. The once-reflected signal is mainly absorbed by the impedance matching circuit and only a small twice-reflected signal 506 is reflected back towards the transducer. The twice-reflected signal 506 is not fully eliminated due to the remaining small residual mismatch caused by the tolerances of the coaxial cable and the imperfection of the circuit. The small twice-reflected signal 506 arrives at the transducer after the propagation delay and is considered to be a second pulse 508 emitted by the transmitter circuit from the transducer's perspective. The second pulse 508 causes the transducer to create a second ultrasonic wave in the material, for which a front wall echo and a back wall echo will be received. However, the amplitude of the second pulse 508 is so small that the front wall echo of the second pulse 508 will be negligible with respect to the amplitude of the back wall echo of the first pulse 507.

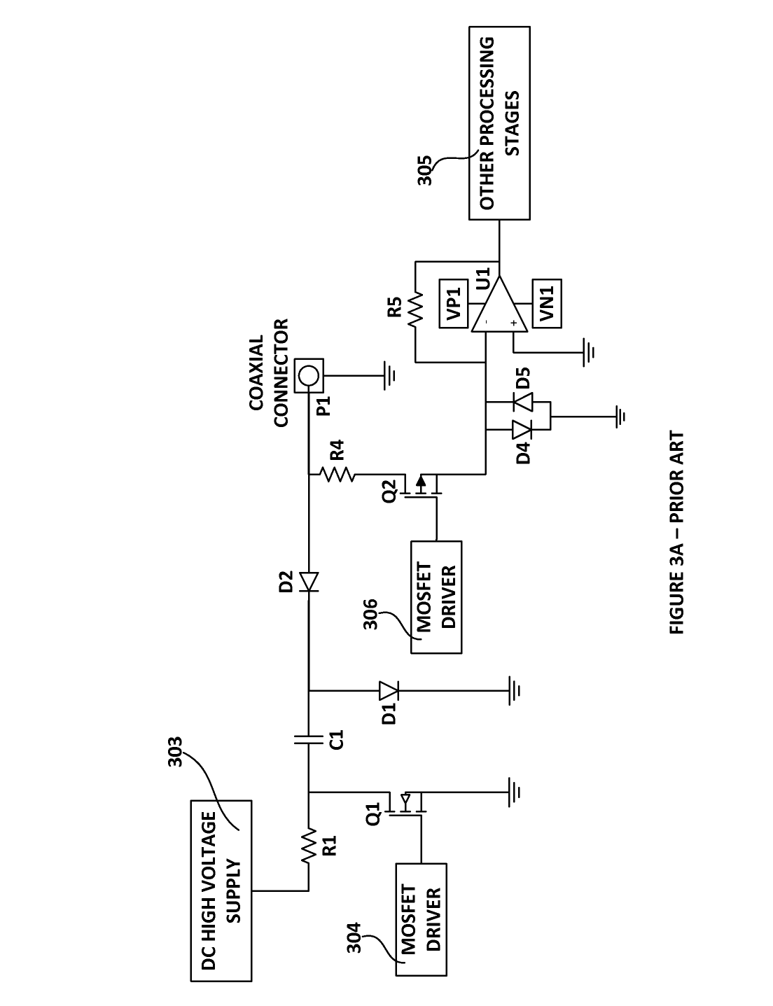

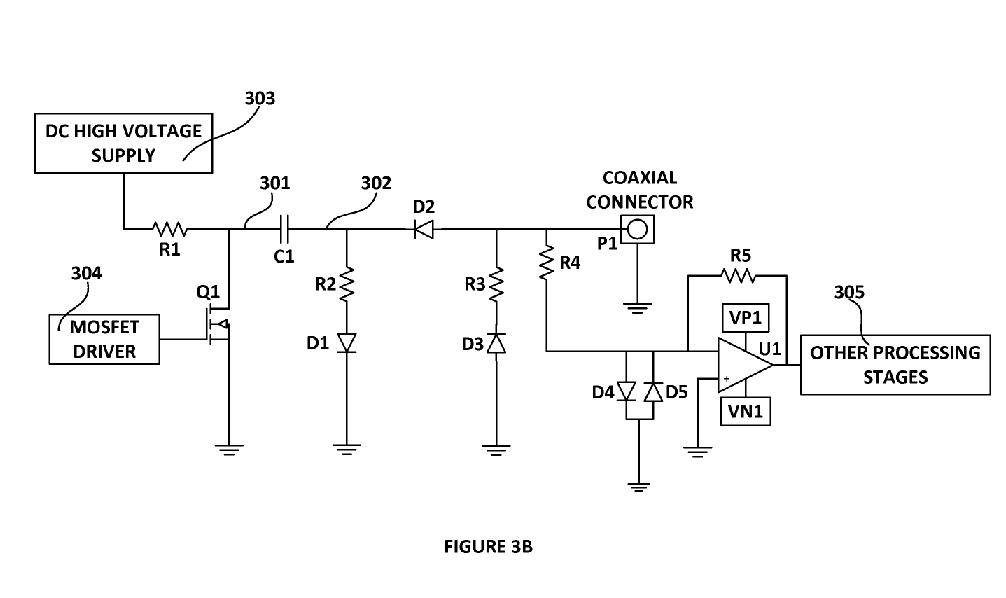

FIG. 3A (prior art) shows an example conventional electronic circuit design for an ultrasonic transmitter-receiver. The transmitter circuit includes DC high voltage supply 303, capacitor C1, resistor R1, diode D1, MOSFET driver 304, MOSFET Q1 and diode D2. The receiver circuit includes resistor R4, MOSFET Q2, MOSFET driver 306, diode D4, diode D5, resistor R5, operational amplifier U1 and other processing stages 305. The coaxial connector P1 and the coaxial cable (not shown) are shared by both the transmitter and receiver circuits.

The DC high voltage supply 303 provides a positive DC voltage to charge the capacitor C1 by the resistor R1, the capacitor C1 and the diode D1 path. The MOSFET driver 304 circuit provides a positive pulse wave shape signal when a pulse is triggered and the MOSFET Q1 is ON. Otherwise, the MOSFET driver 304 provides a voltage close to 0 V. The MOSFET Q1 is OFF when the MOSFET driver 304 is at about 0 V. When the MOSFET Q1 is ON a negative pulse voltage is present at coaxial connector P1 and some current flows through the transducer by D2, coaxial connector P1 and the coaxial cable. MOSFET Q2 controlled by MOSFET driver 306 is an interrupter that is OFF during the transmission of the signal pulse. MOSFET Q2 is ON after the transmission of the signal pulse for acquiring the echo signals by the receiver circuit. The behavior of Q2 is the inverse of Q1. When the MOSFET driver 304 goes back to 0 V, the MOSFET Q1 stops to conduct and the capacitor C1 starts recharging by the R1, C1, D1 path.

After finishing the transmission of the signal pulse, if there is a signal reflected from the transducer to the circuit, the impedance seen by the signal is not matched to the coaxial cable impedance. More precisely, if a relatively large positive signal reflection comes back from the transducer, the impedance seen by the signal is the sum of the impedance of diode D2 and diode D1. This impedance is typically lower than 5Ω which creates major reflection in the cable. If a relatively large negative signal reflection comes back from the transducer, the impedance seen by the signal is the sum of resistor R4, the impedance of the MOSFET Q2 and the impedance of the diode D5. Indeed, MOSFET Q2 in series with R4, saturates when a large current passes from its drain to its source and then its impedance is relatively high. The sum of the impedance is much more than the impedance required to avoid reflection.

Other stages of amplification and signal processing 305 can be carried out on the signal.

FIG. 3B shows an example transmitter-receiver circuit where some components have been added or modified when compared to that of FIG. 3A to get matched impedance when a pulse signal is reflected on the transducer back towards the transmitter circuit. The added components in the transmitter circuit are: resistor R2 in series with diode D1, path R3-D3 in parallel to path D1-R2-D2 which includes resistor R3 in series with diode D3. In the receiver circuit, MOSFET Q2 and its MOSFET driver 306 are replaced by a short circuit.

The DC high voltage supply 303 provides a positive DC voltage to charge the capacitor C1 by the resistor R1, the capacitor C1, the resistor R2 and the diode D1 path. The MOSFET driver 304 circuit provides a positive pulse wave shape signal when a pulse is triggered and the MOSFET Q1 is ON. Otherwise, the MOSFET driver 304 provides a voltage close to 0 V. The MOSFET Q1 is OFF when the MOSFET driver 304 is at about 0 V. When the MOSFET Q1 goes ON, the measure point 301 drops close to 0 V and the measure point 302 drops in negative voltage due to the charge of the capacitor C1. Some current flows through the transducer by D2, coaxial connector P1 and the coaxial cable. Some current also flows in R3, D3, R4 and D5. When the MOSFET driver 304 goes back to 0 V, the MOSFET Q1 stops to conduct and the capacitor C1 starts recharging by the R1, C1, R2 and D1 path.

After finishing transmission of the signal pulse, if there is a signal reflected from the transducer to the circuit, the circuit absorbs the reflection because the circuit has the same impedance as the coaxial cable.

More precisely, if a relatively large positive signal reflection comes back from the transducer, the impedance seen by the signal is resistor R4 in parallel with resistor R2 in parallel with R1, assuming the voltage drop in diode D1, diode D2, diode D4 and capacitor C1 are negligible. To avoid reflection, R4//R2//R1 should be equal to the coaxial cable impedance. If the coaxial cable impedance is 50Ω, R4//R2//R1 should equal to 50Ω.

If a relatively large negative signal reflection comes back from the transducer, the impedance seen by the signal is resistor R4 in parallel with R3, assuming the voltage drop in the diode D3 and the diode D5 are negligible. To avoid reflection R4//R3 should be equal to the coaxial cable impedance. If the coaxial cable impedance is 50Ω, R4//R3 should equal to 50Ω.

For example, if a 50Ω coaxial cable impedance is used and R4 equals 100Ω and R3 equals 100Ω, a 50Ω impedance (R4//R3=50Ω) is obtained which absorbs the negative signal reflection from the transducer. In the same manner if R4 is equal to 100Ω and R2 is set at 110Ω and R1 at 1100Ω, a 50Ω impedance (R4//R2//R1) is obtained which absorbs a positive signal reflection from the transducer.

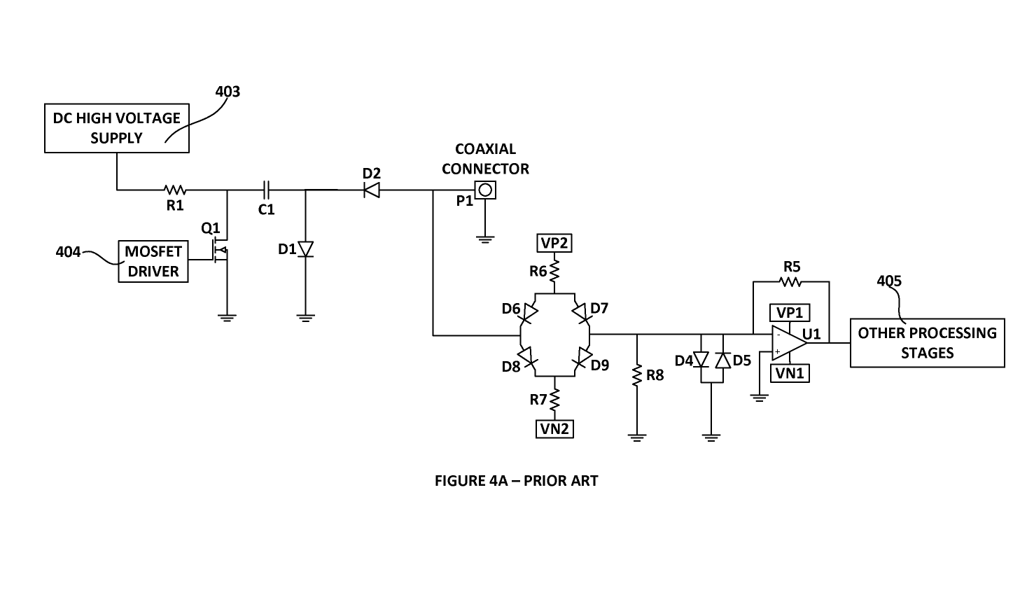

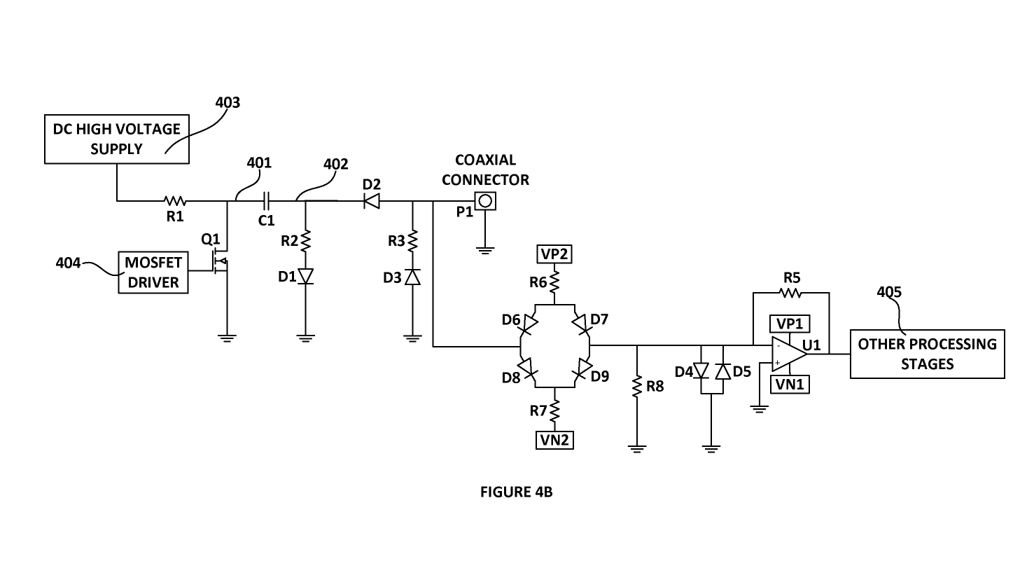

FIG. 4A (prior art) shows an example of another conventional electronic circuit design for an ultrasonic transmitter-receiver. The transmitter circuit is identical to that of FIG. 3A. The receiver circuit is different from that of FIG. 3A. Resistor R4, MOSFET Q2 and MOSFET driver 306 are omitted. Resistor R6, resistor R7, resistor R8, diode D6, diode D7, diode D8 and diode D9 are added.

In transmission mode, the circuit of FIG. 4A behaves like the circuit of FIG. 3A. In receiver mode, if a relatively large positive signal reflection comes back from the transducer, the impedance seen by the signal is typically lower than 5Ω which creates major reflection in the cable. If a relatively large negative signal reflection comes back from the transducer, the impedance seen by the signal is much more than the impedance required to avoid reflection. Indeed, R6 is typically greater than 200Ω.

Other stages of amplification and signal processing 405 can be carried out on the signal.

FIG. 4B shows an example transmitter-receiver circuit where some components have been added or modified when compared to that of FIG. 4A to get matched impedance when a pulse signal is reflected on the transducer back towards the transmitter circuit. The added components in the transmitter circuit of FIG. 4B are: resistor R2 in series with diode D1, path R3-D3 in parallel to path R2-D2 which includes resistor R3 in series with diode D3. The receiver circuit of FIG. 4B is identical to that of FIG. 4A.

The DC high voltage supply 403 providing a positive DC voltage to charge capacitor C1 by resistor R1, capacitor C1, resistor R2 and diode D1 path. The MOSFET driver 404 circuit provides a positive pulse wave shape signal when a pulse is triggered and the MOSFET Q1 is ON. Otherwise, the MOSFET driver 404 provides a voltage close to 0 V. The MOSFET Q1 is OFF when the MOSFET driver 404 is at about 0 V. When Q1 goes ON, the measure point 401 drops close to 0 V and the measure point 402 drops in negative voltage due to the charge of the capacitor C1. Some current flows through the transducer by D2, coaxial connector P1 and the coaxial cable. Some current also flows in R3, D3, R6 and D6. When the MOSFET driver 404 goes back to 0 V, the MOSFET Q1 stops to conduct and the capacitor C1 starts recharging by the R1, C1, R2 and D1 path.

After finishing the transmission of the signal pulse, if there is a signal reflected from the transducer to the circuit, the circuit absorbs the reflection because the circuit has the same impedance as the coaxial cable.

More precisely, if a relatively large positive signal reflection comes back from the transducer, the impedance seen by the signal is resistor R7 in parallel with R2 in parallel with R1, assuming the voltage drop in diode D8, diode D2, diode D1 and capacitor C1 are negligible. To avoid reflection R7//R2//R1 should be equal to the coaxial cable impedance.

If a relatively large negative signal reflection comes back from the transducer, the impedance seen by the signal is resistor R6 in parallel with R3, assuming that the voltage drop in diode D3 and diode D6 is negligible. To avoid reflection, R6//R3 should be equal to the coaxial cable impedance.

For example, if a 50Ω coaxial cable impedance is used and R6 equal 300Ω and R3 equals 60Ω, a 50Ω impedance (R6//R3=50Ω) is obtained, which absorbs a negative signal reflection from the transducer. Similarly, if R7=R6=300Ω and R2 is 63Ω and R1 is 1260Ω, a 50Ω impedance (R7//R2//R1) is obtained, which absorbs a positive signal reflection from the transducer.

It is important to note that the impedance matching circuit matches the cable impedance of the cable at the transmitter circuit for an electrical parasitic reflection signal of the electrical pulse voltage signal. The electrical parasitic reflection signal is caused by an impedance mismatch between the cable and the ultrasonic transducer. The parasitic nominal voltage value is at most equal to the pulse nominal voltage value. The impedance matching circuit does not match the impedance of the cable at the receiver circuit such as to prevent reflecting the transducer emitted pulse. The transducer emitted pulses are low voltage signals which, even when reflected, only cause low voltage parasitic signals which can be readily ignored during signal processing.

The electrical parasitic reflection signal caused by a reflection of the electrical pulse voltage signal emitted by the transmitter has a nominal value which can reach the nominal value of the original electrical pulse voltage signal and its impact is much more important on the acquired signals. It can cause a significant ambiguity. Its shape can have a positive component and an inverted component.

Example nominal voltage values for the electrical pulse voltage signal emitted by the transmitter are between −50 V and −400 V and example nominal voltage values for the signals emitted by the transducer are smaller than +/−1 V.

As will be readily understood, it is not necessary for the impedance matching circuit to fully eliminate the reflection of the pulse. A significant reduction of its nominal voltage value will allow discriminating it in the results.

As will be readily understood, the length of the cable between the transmitter circuit and the transducer at which the impedance matching circuit becomes relevant is related to the thickness of the material to be tested. If the length of a return trip of the signal in the cable corresponds to the length of a return trip of the ultrasonic wave in the material to be tested, an ambiguity will be created in the acquired voltage signal using conventional systems.

Vc is the electrical signal propagation speed in a cable used for the ultrasonic testing system, namely 2×10⁸ m/s +/−20%. Let us consider it is 2×10⁸ m/s. Vp is the speed of sound in a material under test, typically between 4000 and 6000 m/s. Let us consider it is 5000 m/s. Let us assume that the minimal thickness of the material to be tested is Emin=0.5×10⁻³m and that the maximum thickness of the material to be tested is Emax=3.0×10⁻³m. Lc is the length of the cable.

The time required for a return trip of the ultrasonic wave in the material to be tested is Tp=2×E/Vp. The time required for a return trip of the electrical signal in the cable is Tc=2×Lc/Vc. The ambiguity is present in the acquired voltage signal using conventional systems when Tp=Tc, namely when 2×E/Vp=2×Lc/Vc which yields Lc=E×Vc/Vp. At Emin, Lc is (0.5×10⁻³ m)×(2×10⁸ m/s)/(5000 m/s)=20 m. At Emax, Lc is (3.0×10⁻³ m)×(2×10⁸ m/s)/(5000 m/s)=120 m.

In this example, the impedance matching circuit is useful when the cable length is between 20 m and 120 m, namely when the cable has a length which is 40 000 times ((2×10⁸ m/s)/(5000 m/s) longer than the thickness of the material to be tested. Outside of this range of cable lengths, the impedance matching circuit may not be required but still would not cause any negative impact on the acquired signals.

As will be readily understood, the impedance matching circuit can be designed to match any cable impedance. Standard cable impedances available in today's market include 50, 75, 93 and 95 ohms Cables with other cable impedances could be used in the present system without departing from the invention. The matched cable impedance could be the nominal cable impedance or a tested actual cable impedance.

As will be readily understood, other impedance matching circuits which are adapted to match the cable impedance of the cable at the transmitter circuit for an electrical parasitic reflection signal of the electrical pulse voltage signal are equivalents to the example circuits detailed herein. In particular, one skilled in the art will appreciate that the diodes and MOSFET elements could be replaced by semiconductor rectifiers, switches and interrupters in general. One skilled in the art will select a set of appropriate circuit components to match the impedance and may elect to use two or more resistors or diodes in series or in parallel in place of the illustrated single resistor or diode. Moreover, the DC high voltage supply may provide a negative DC voltage in an inverted impedance matching circuit.

As will be further understood, the transmitter circuit could be designed to emit a positive or negative electrical pulse voltage signal. Alternatively, the transmitter circuit could be designed to emit a bipolar pulse, namely a pulse with consecutive positive and negative components, in any order.

The embodiments described above are intended to be exemplary only. The scope of the invention is therefore intended to be limited solely by the appended claims.

1. A transmitter circuit for an ultrasonic thickness measurement system having an ultrasonic transducer and a cable with known cable impedance, said cable connecting at least said transmitter circuit to said ultrasonic transducer, said transmitter circuit comprising:
an electrical pulse voltage signal emitter for producing an electrical pulse voltage signal to be propagated over said cable to said ultrasonic transducer, said electrical pulse voltage signal having a pulse nominal voltage value;
a matched impedance circuit for matching a cable impedance of said cable at said transmitter circuit for an electrical parasitic reflection signal of said electrical pulse voltage signal, said electrical parasitic reflection signal being caused by an impedance mismatch between said cable and said ultrasonic transducer, a parasitic nominal voltage value of said electrical parasitic reflection signal being at most said pulse nominal voltage value.

2. The transmitter circuit as claimed in claim 1, wherein a shape of said electrical parasitic reflection signal has at least one of a positive component and a negative component.

3. The transmitter circuit as claimed in claim 1, wherein said cable impedance of said cable is one of 50, 75, 93 and 95 ohms.

4. The transmitter circuit as claimed in claim 1, wherein said pulse nominal voltage value is between −50 V and −400 V.

5. The transmitter circuit as claimed in claim 1, wherein said matched impedance circuit is at least one resistance provided in said transmitter circuit to impact a circuit impedance of said transmitter circuit for said electrical parasitic reflection signal, said circuit impedance matching said cable impedance.

6. The transmitter circuit as claimed in claim 5, wherein said matched impedance circuit further includes at least one diode, said at least one diode controlling an effect of said at least one resistance on said circuit impedance.

7. The transmitter circuit as claimed in claim 6, wherein said matched impedance circuit is one resistance in series with a diode in which current circulates during transmission of said electrical pulse voltage signal.

8. The transmitter circuit as claimed in claim 7, wherein said matched impedance circuit is one resistance in series with a diode in which current circulates after said transmission of said electrical pulse voltage signal has ended.

9. A method for reducing an impact of an electrical parasitic reflection signal in an ultrasonic measurement system having a transmitter circuit, an ultrasonic transducer and a cable with known cable impedance, said cable connecting at least said transmitter circuit to said ultrasonic transducer, comprising:
emitting an electrical pulse voltage signal at said transmitter circuit;
propagating said electrical pulse voltage signal having a pulse nominal voltage value over said cable to said ultrasonic transducer;
receiving, at said transmitter circuit, an electrical parasitic reflection signal caused by an impedance mismatch between said cable and said ultrasonic transducer, a parasitic nominal voltage value of said electrical parasitic reflection signal being at most said pulse nominal voltage value;
matching an impedance of said cable at said transmitter circuit for said electrical parasitic reflection signal.

10. The method as claimed in claim 9, wherein a shape of said electrical parasitic reflection signal has at least one of a positive component and a negative component.

11. The method as claimed in claim 9, wherein said cable impedance of said cable is one of 50, 75, 93 and 95 ohms.

12. The method as claimed in claim 9, wherein said pulse nominal voltage value is between −50 V and −400 V.

13. The method as claimed in claim 9, wherein said matching comprises providing at least one resistance in said transmitter circuit to impact a circuit impedance of said transmitter circuit for said electrical parasitic reflection signal, said circuit impedance matching said cable impedance.

14. The method as claimed in claim 13, wherein said matching further comprises providing at least one diode, said at least one diode controlling an effect of said at least one resistance on said circuit impedance.

15. The method as claimed in claim 14, wherein matching comprises providing one resistance in series with a diode in which current circulates during transmission of said electrical pulse voltage signal.

16. The method as claimed in claim 15, wherein said matching comprises providing one resistance in series with a diode in which current circulates after said transmission of said electrical pulse voltage signal has ended.
